(19) United States
(12) Patent Application Publication
(10) Pub. No.: US 2016/0131953 A1
(43) Pub. Date: May 12, 2016

(54) LIQUID CRYSTAL DISPLAY PANEL AND METHOD FOR MANUFACTURING LIQUID CRYSTAL DISPLAY PANEL

(71) Applicant: Shenzhen China Star Optoelectronics Technology Co. Ltd., Guangdong (CN)

(72) Inventors: Hongyuan XU, Guangdong (CN); Bo SUN, Guangdong (CN)

(21) Appl. No.: 14/415,673

(22) PCT Filed: Nov. 17, 2014
(86) PCT No.: PCT/CN2014/091297

§ 371 Date: Jan. 19, 2015

(30) Foreign Application Priority Data
Nov. 12, 2014 (CN) 201410635411.8

(51) Int. Cl. G02F 1/1362; G02F 1/1343; H01L 27/12; G02F 1/1368

(52) U.S. Cl. CPC G02F 1/136286; G02F 1/1368; G02F 1/134309; G02F 1/136227; H01L 27/1262; G02F 2001/133357

(57) ABSTRACT

A liquid crystal display panel and a manufacturing method thereof are provided. The liquid crystal display panel includes a color resist layer, a planarization layer, and a pixel electrode layer. The color resist layer includes a first color resist unit and a second color resist unit, both of which are respectively disposed in two adjacent pixel units. The first color resist unit and the second color resist unit herein form a common boundary above the data line. The planarization layer is disposed on the color resist layer and utilized to planarize the common boundary. The pixel electrode layer which is disposed on the planarization layer includes a plurality of pixel electrode patterns corresponding to the pixel units, and borderlines of two adjacent pixel electrode patterns are located above the data line. The liquid crystal display panel of the present invention omits a black matrix for enhancing aperture ratio.

### TECHNICAL FIELD OF THE INVENTION

The present invention relates to a liquid crystal display (LCD) technology, and especially to an LCD panel and a method for manufacturing the LCD panel.

### BACKGROUD OF THE INVENTION

A liquid crystal display is a widely used flat panel display, and it realizes an image display mainly by a liquid crystal switch to modulate light intensity of a backlight source. A structure of traditional liquid crystal display mainly includes three layers: a thin film transistor (TFT) array substrate for controlling electric field strength of the LCD, a liquid crystal layer, and a color filter (CF) substrate. A Color filter On Array (COA) substrate is a technique for disposing RGB color resists of the CF substrate onto the TFT array substrate. Since the COA substrate can reduce a coupling between pixel electrodes and metal wires, a signal delay condition occurring on the metal wires is improved. Therefore, using the COA substrate can significantly decrease a degree of parasitic capacitance, enhance an aperture ratio of the panel, and improve a display quality of the panel.

However, in the liquid crystal display employing the COA substrate, different gray scale voltages are applied to a region between two adjacent RGB color resists, so a disorder phenomenon of the liquid crystal molecules often occurs near a common boundary of pixel units. Therefore, there is a need to dispose a black matrix (BM) between the two adjacent RGB color resists to separate them, or to dispose the black matrix on the corresponding region of an upper substrate, thereby blocking wrong display of colors. However, this will lose a significant portion of the aperture ratio. Moreover, in the application of curved displays, if the upper substrate is equipped with the BM, BM offsets due to the curved panel will cause light leakage.

### SUMMARY OF THE INVENTION

An objective of the present invention is to provide a liquid crystal display panel, which can omit the black matrix on the COA substrate by the shield of a data line solve, thereby improving the aperture ratio of the display and preventing the light leakage caused by the curved panel.

Another objective of the present invention is to provide a method for manufacturing a liquid crystal display panel, which can omit the disposal of the black matrix for improving the aperture ratio of the display and preventing the light leakage caused by the curved panel.

To achieve the foregoing objective, a preferred embodiment of the present invention provides a liquid crystal display panel, which includes a first substrate and a second substrate opposite to each other, and a liquid crystal layer disposed between the first substrate and the second substrate. The second substrate includes a plurality of data lines, scan lines, and thin film transistors, and the data lines and the scan lines define a plurality of pixel units. The liquid crystal display panel further includes a color resist layer, a planarization layer, and a pixel electrode layer. The color resist layer is disposed on the second substrate. The color resist layer includes a first color resist unit and a second color resist unit, and the first color resist unit and the second color resist unit are respectively disposed in two adjacent pixel units. The first color resist unit and the second color resist unit herein form a common boundary above the data line. The planarization layer is disposed on the color resist layer and utilized to planarize the common boundary. The pixel electrode layer is disposed on the planarization layer. The pixel electrode layer includes a plurality of pixel electrode patterns corresponding to the pixel units, and borderlines of two adjacent pixel electrode patterns are located above the data line.

In the preferred embodiment the present invention, the first color resist unit overlaps with the second color resist unit. In addition, the data line has a predetermined width and defines a strip of shaded region. Preferably, the first color resist unit overlaps with the second color resist unit within the strip of shaded region.

In the preferred embodiment the present invention, the common boundary is located within the strip of shaded region. More specifically, the borderlines of the two adjacent pixel electrode patterns are located within the strip of shaded region.

In the preferred embodiment the present invention, the liquid crystal display panel further includes a passivation layer formed between the second substrate and the color resist layer. In addition, the liquid crystal display panel further includes a via hole penetrating through the passivation layer, the color resist layer, and the planarization layer, and the pixel electrode layer is coupled to the thin film transistor through the via hole.

In the preferred embodiment of the present invention, the first substrate and the second substrate are curved.

Similarly, to achieve the foregoing objective, another preferred embodiment of the present invention provides a method for manufacturing a liquid crystal display panel, which includes: providing a second substrate comprising a plurality of data lines, scan lines, and thin film transistors, wherein the data lines and the scan lines define a plurality of pixel units; forming a color resist layer on the second substrate, wherein the color resist layer comprises a first color resist unit and a second color resist unit, the first color resist unit and the second color resist unit respectively disposed in two adjacent pixel units, wherein the first color resist unit and the second color resist unit form a common boundary above the data line; coating a planarization layer on the color resist layer; coating a pixel electrode layer on the planarization layer; and patterning the pixel electrode layer to form a plurality of pixel electrode patterns corresponding to the pixel units, wherein two adjacent pixel electrode patterns have borderlines located above the data line.

In the preferred embodiment the present invention, before coating the pixel electrode layer, the method further includes patterning the planarization layer and the color resist layer to form a via hole penetrating through the color resist layer and the planarization layer for exposing the thin film transistor.

In comparison with the prior art, the present invention further forms the planarization layer on the color resist layer so as to eliminate a sectional difference on the common boundary of the first color resist unit and the second color resist unit. Thus, a longitudinal BM on the first substrate can be omitted, thereby enhancing the aperture ratio. In curved displays, since there is no longitudinal BM on the first substrate, the light leakage caused by the longitudinal BM offsets due to the curved panel can be avoided.

It is to be understood that both the foregoing general description and the following detailed description of the present invention are exemplary and explanatory and are intended to provide further explanation of the invention as claimed.

### BRIEF DESCRIPTION OF THE DRAWINGS

FIG. 1 is a sectional view schematically illustrating a liquid crystal display panel according to one preferred embodiment of the present invention;

FIG. 2 is a top view schematically illustrating a second substrate according to the preferred embodiment of the present invention;

FIG. 3 is a flow chart illustrating a method for manufacturing the liquid crystal display panel according to one preferred embodiment of the present invention;

FIG. 4A is a schematic drawing illustrating step S20;

FIG. 4B is a schematic drawing illustrating step S30;

FIG. 4C is a schematic drawing illustrating step S40;

FIG. 4D is a schematic drawing illustrating step S50; and

FIG. 4E is a schematic drawing illustrating step S60.

### DETAILED DESCRIPTION OF THE INVENTION

Descriptions of the following embodiments refer to attached drawings which are utilized to exemplify specific embodiments.

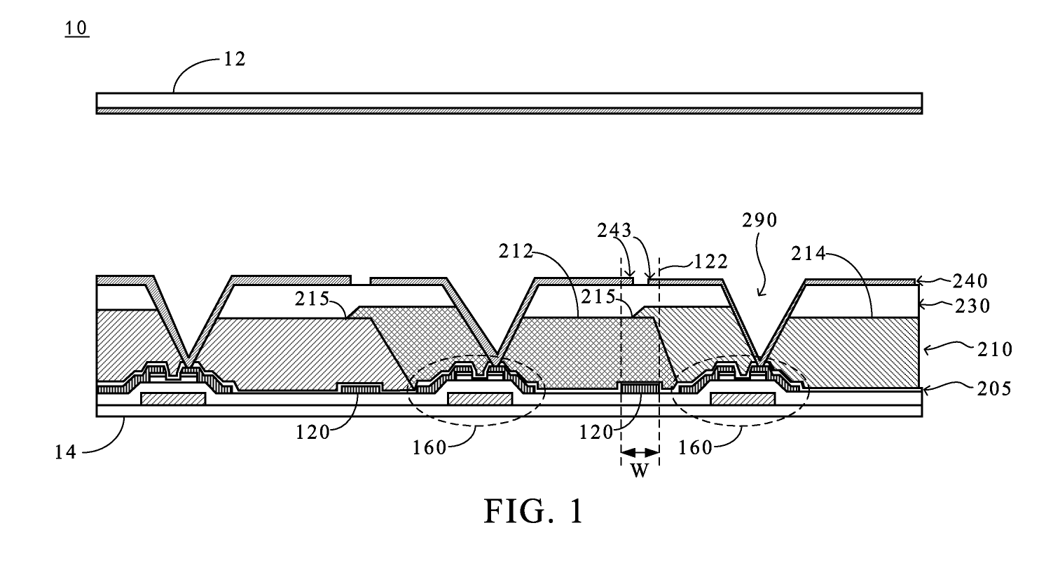

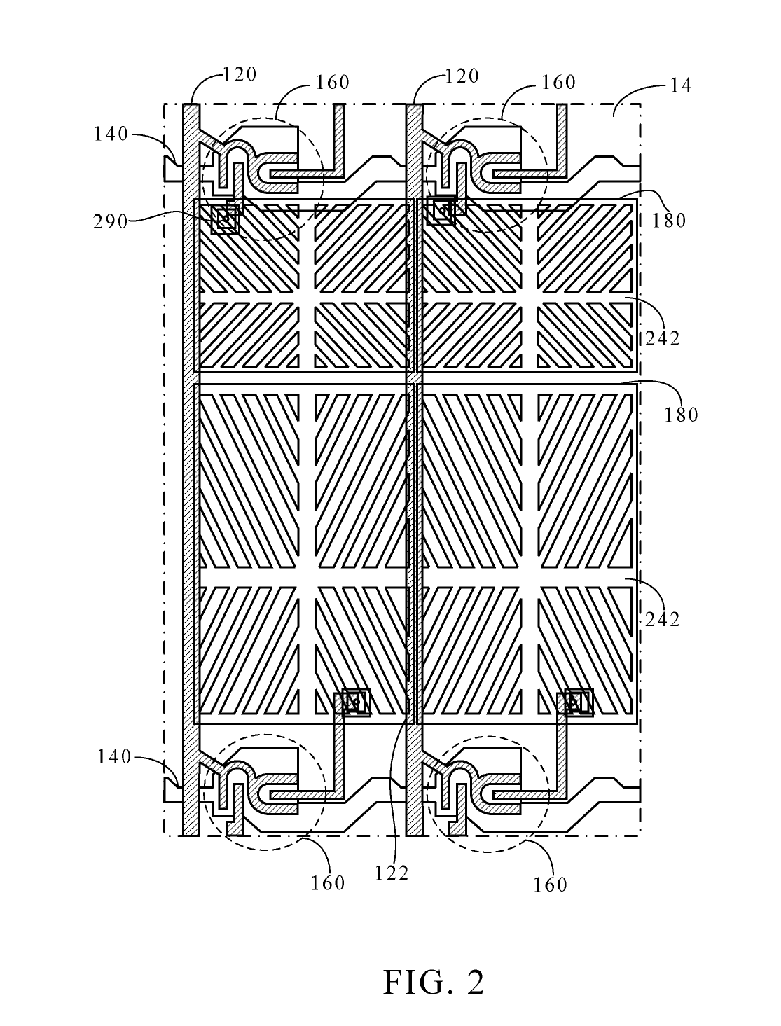

Referring to FIG. 1 and FIG. 2, FIG. 1 is a sectional view schematically illustrating a liquid crystal display panel according to one preferred embodiment of the present invention; FIG. 2 is a top view schematically illustrating a second substrate according to the preferred embodiment of the present invention. It should be noted that the above-mentioned drawings are just for explanation, and they are not depicted in real proportion. The liquid crystal display panel 10 of the embodiment includes a first substrate 12 and a second substrate 14 opposite to each other, and a liquid crystal layer (not shown) disposed between the first substrate 12 and the second substrate 14. Preferably, the first substrate 12 can be known as an upper substrate, and the second substrate 14 can be known as a lower substrate. The second substrate 14 includes a plurality of data lines 120, scan lines 140, and thin film transistors 160. The data lines 120 and the scan lines 140 define a plurality of pixel units 180 (or sub pixels).

As shown in FIG. 1, the second substrate 14 further has a color resist layer 210 that is disposed on the second substrate 14 such that the second substrate 14 forms a COA substrate. The color resist layer 210 includes a first color resist unit 212 and a second color resist unit 214. Specifically, the color resist layer 210 includes red, green, and blue color resist units. The first color resist unit 212 and the second color resist unit 214 of the embodiment can be arbitrary two of the red, green, and blue color resist units, such as red and green; green and blue; or red and blue color resist units.

As shown in FIG. 1, the first color resist unit 212 and the second color resist unit 214 are respectively disposed in the two adjacent pixel units 180, and shapes of the first color resist unit 212 and the second color resist unit 214 are identical to the pixel unit 180. In the embodiment, the first color resist unit 212 and the second color resist unit 214 form a common boundary 215 above the data line 120. It is worth mentioning that there is no need to dispose a black matrix between the first color resist unit 212 and the second color resist unit 214 to separate both in the embodiment. Therefore, on common boundary 215, the first color resist unit 212 overlaps with the second color resist unit 214, and there is a height gap.

More specifically, the data line 120 has a predetermined width W and defines a strip of shaded region 122 (as shown in FIG. 2). That is to say, the strip of shaded region 122 is an elongated shape along the data lines 120. Therefore, as shown in FIG. 1, the first color resist unit 212 overlaps with the second color resist unit 214 within the strip of shaded region 122. That is to say, the common boundary 215 is located within the strip of shaded region 122.

As shown in FIG. 1, the second substrate 14 further has a planarization layer 230 that is disposed on the color resist layer 210. The planarization layer 230 planarizes the common boundary 215 between the first color resist unit 212 and the second color resist unit 214 for eliminating the sectional difference of the common boundary 215. Preferably, the planarization layer 230 may be made of transparent organic material. Since the sectional difference above data line 120 has been eliminated, there is no need to dispose the BM on the first substrate 12 for shading, and thus the aperture ratio can be set to maximization.

Referring to FIG. 1 and FIG. 2 again, the second substrate 14 further has a pixel electrode layer 240 that is disposed on the planarization layer 230. The pixel electrode layer 240 includes a plurality of pixel electrode patterns 242 corresponding to the pixel units 180, and two adjacent pixel electrode patterns 242 have borderlines 243 which are located above the data line 120. That is to say, the borderlines 243 of the two adjacent pixel electrode patterns 242 are located within the strip of shaded region 122. Therefore, the data line 120 can shade the light from the backlight passing through disordered liquid crystals caused by the differences of the electric field between the adjacent pixel electrode patterns without the BM for the shading.

It is worth mentioning that the second substrate 14 further includes a passivation layer 205 formed between the second substrate 12 and the color resist layer 210, thereby protecting the TFT array substrate. As shown in FIG. 2, the liquid crystal display panel 10 further includes a via hole 290 penetrating through the passivation layer 205, the color resist layer 210, and the planarization layer 230. Moreover, the pixel electrode layer 240 is coupled to the thin film transistor 160 through the via hole 290. Specifically, the pixel electrode pattern 242 is coupled to a drain of the thin film transistor 160 through the via hole 290.

In the liquid crystal display panel of other embodiments, When the first substrate 12 and the second substrate 14 are curved, that is, as the liquid crystal display panel of a curved display, there will be no problem of the light leakage due to the BM offsets.

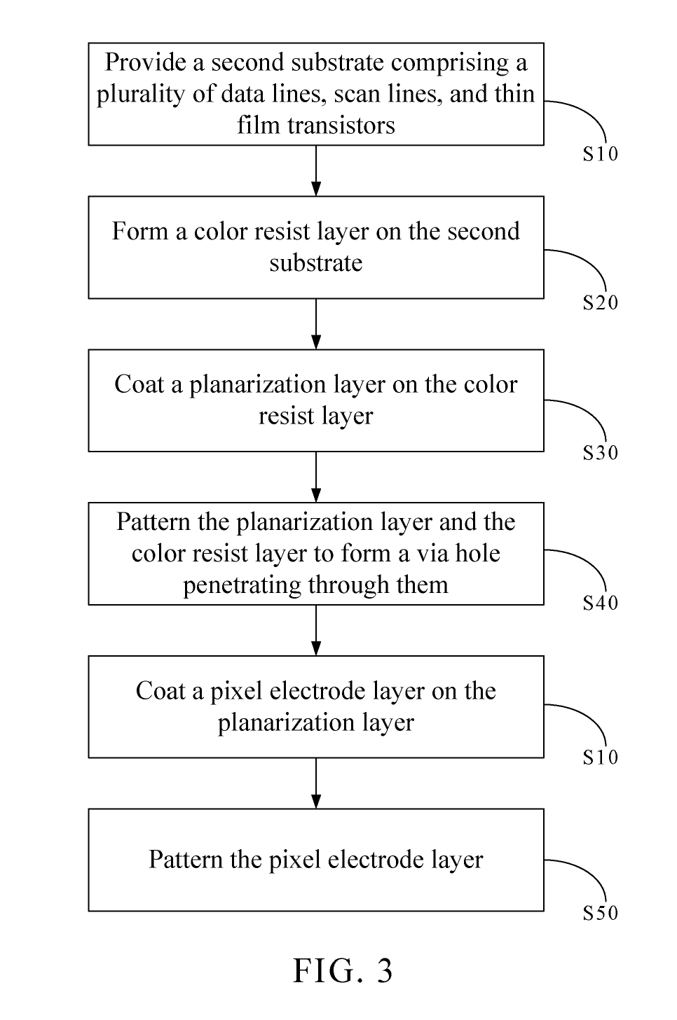

The method for manufacturing the liquid crystal display panel in the preferred embodiment of the present invention will be explained in detail in the following description. Referring to FIG. 1 to FIG. 3, FIG. 3 is a flow chart illustrating a method for manufacturing the liquid crystal display panel according to one preferred embodiment of the present invention. The method for manufacturing the liquid crystal display panel of the embodiment begins with step S10.

In step S10, a second substrate 14 including a plurality of data lines 120, scan lines 140, and thin film transistors 160 is provided, and then execution resumes at step S20. The data lines 120 and the scan lines 140 herein define a plurality of pixel units 180. The step is well-known to a person skilled in the art, so no further detail will be provided herein.

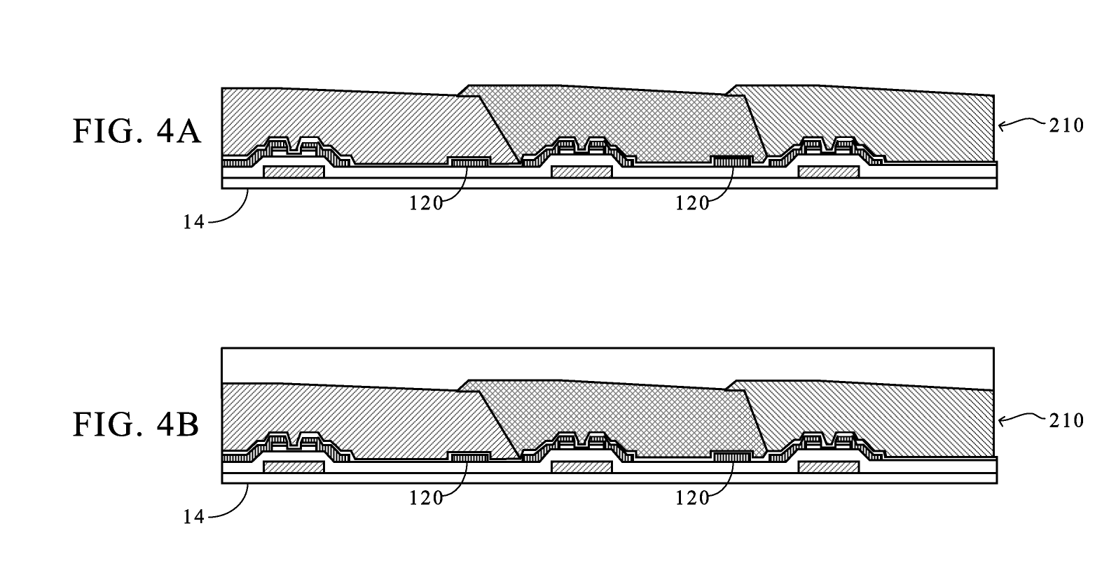

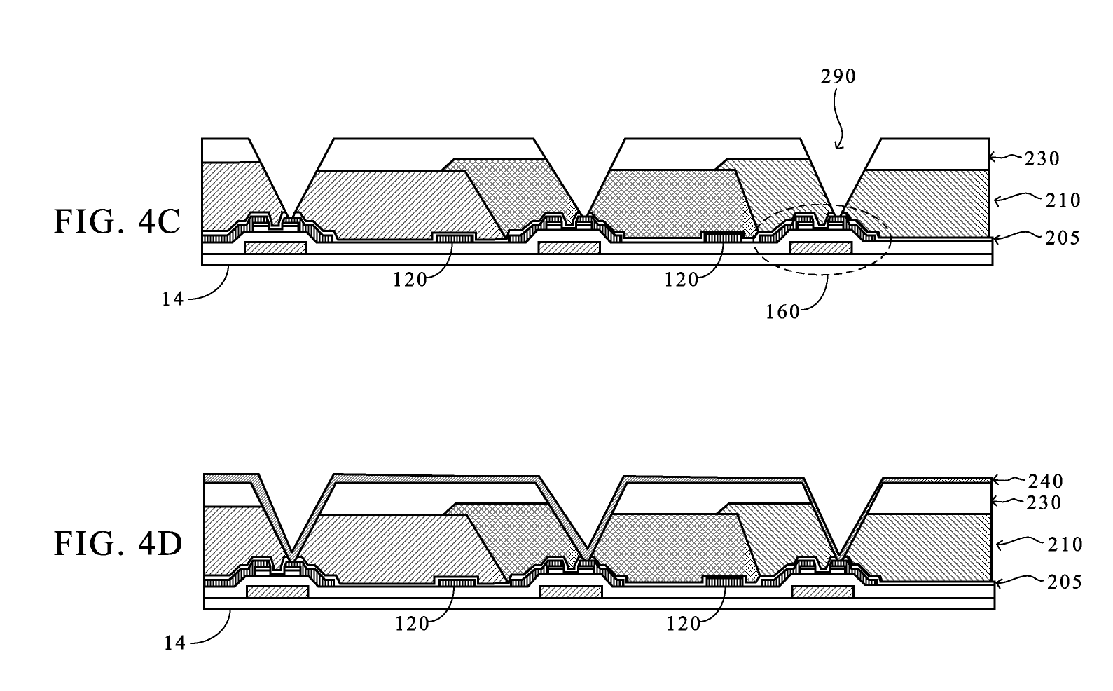

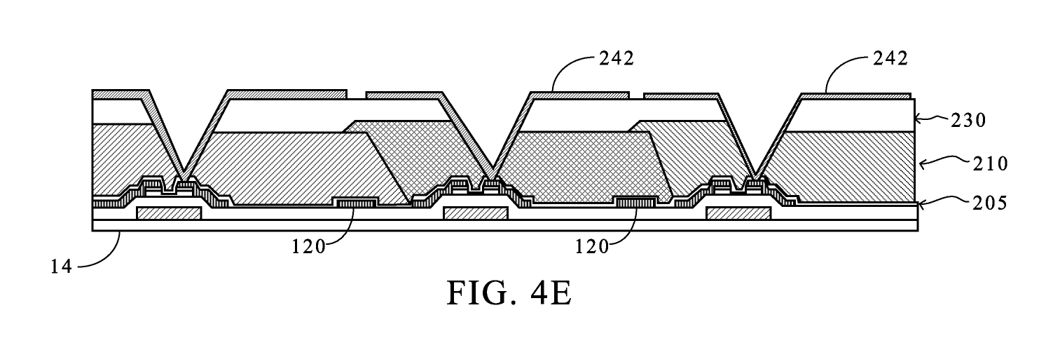

Referring to FIG. 4A, FIG. 4A is a schematic drawing illustrating step S20. In step S20, a color resist layer 210 (i.e. red, green and blue color resists) is formed on the second substrate 14, and then execution resumes at step S30. The color resist layer 210 includes a first color resist unit 212 and a second color resist unit 214. The first color resist unit 212 and the second color resist unit 214 are respectively disposed in the two adjacent pixel units 180. The first color resist unit 212 and the second color resist unit 214 herein form a common boundary 215 above the data line 120.

Referring to FIG. 4B, FIG. 4B is a schematic drawing illustrating step S30. In step S30, a planarization layer 230 is coated on the color resist layer 210, and then execution resumes at step S40. Specifically, the planarization layer 230 may be made of transparent organic material.

Referring to FIG. 4C, FIG. 4C is a schematic drawing illustrating step S40. In step S40, the planarization layer 230 and the color resist layer 210 are patterned to form a via hole 290 penetrating through the color resist layer 210 and the planarization layer 230 for exposing the thin film transistor 160, and then execution resumes at step S50. Specifically, the patterning step is achieved by a photomask process.

Referring to FIG. 4D, FIG. 4D is a schematic drawing illustrating step

S50. In step S50, a pixel electrode layer 240 is coated on the planarization layer 230, and then execution resumes at step S60. Specifically, the pixel electrode layer 240 also covers a part of the color resist layer 210 and the drain of the thin film transistor 160 within the via hole 290. Specifically, the pixel electrode layer 240 is indium tin oxide (ITO).

Referring to FIG. 1 and FIG. 4E, FIG. 4E is a schematic drawing illustrating step S60. In step S60, the pixel electrode layer 240 is patterned to form a plurality of pixel electrode patterns 242 corresponding to the pixel units 180, and the borderlines 23 of the two pixel electrode patterns 242 are located above the data line. Specifically, the patterning step is achieved by another photomask process.

In summary, the present invention further forms the planarization layer 230 on the color resist layer 210 so as to eliminate the sectional difference on the common boundary 215 of the first color resist unit 212 and the second color resist unit 214. Thus, the longitudinal BM on the first substrate 12 can be omitted, thereby enhancing the aperture ratio. Moreover, in curved displays, since there is no longitudinal BM on the first substrate 12, the light leakage caused by the longitudinal BM offsets due to the curved panel can be avoided.

While the preferred embodiments of the present invention have been illustrated and described in detail, various modifications and alterations can be made by persons skilled in this art. The embodiment of the present invention is therefore described in an illustrative but not restrictive sense. It is intended that the present invention should not be limited to the particular forms as illustrated, and that all modifications and alterations which maintain the spirit and realm of the present invention are within the scope as defined in the appended claims.

What is claimed is:

1. A liquid crystal display panel, comprising a first substrate and a second substrate opposite to each other, and a liquid crystal layer disposed between the first substrate and the second substrate, the second substrate comprising a plurality of data lines, scan lines, and thin film transistors, the data lines and the scan lines defining a plurality of pixel units, the liquid crystal display panel further comprising:
a color resist layer disposed on the second substrate, the color resist layer comprising a first color resist unit and a second color resist unit, the first color resist unit and the second color resist unit respectively disposed in two adjacent pixel units, wherein the first color resist unit and the second color resist unit form a common boundary above the data line, and the first color resist unit overlaps with the second color resist unit on the data line;
a planarization layer disposed on the color resist layer, utilized to planarize the common boundary; and
a pixel electrode layer disposed on the planarization layer, the pixel electrode layer comprising a plurality of pixel electrode patterns corresponding to the pixel units, and borderlines of two adjacent pixel electrode patterns located above the data line.

2. The liquid crystal display panel according to claim 1, wherein the data line has a predetermined width and defines a strip of shaded region.

3. The liquid crystal display panel according to claim 2, wherein the borderlines of the two adjacent pixel electrode patterns are located within the strip of shaded region.

4. The liquid crystal display panel according to claim 1, wherein the first substrate and the second substrate are curved.

5. A liquid crystal display panel, comprising a first substrate and a second substrate opposite to each other, and a liquid crystal layer disposed between the first substrate and the second substrate, the second substrate comprising a plurality of data lines, scan lines, and thin film transistors, the data lines and the scan lines defining a plurality of pixel units, the liquid crystal display panel further comprising:
a color resist layer disposed on the second substrate, the color resist layer comprising a first color resist unit and a second color resist unit, the first color resist unit and the second color resist unit respectively disposed in two adjacent pixel units, wherein the first color resist unit and the second color resist unit form a common boundary above the data line;
a planarization layer disposed on the color resist layer, utilized to planarize the common boundary; and
a pixel electrode layer disposed on the planarization layer, the pixel electrode layer comprising a plurality of pixel electrode patterns corresponding to the pixel units, and borderlines of two adjacent pixel electrode patterns located above the data line.

6. The liquid crystal display panel according to claim 5, wherein the first color resist unit overlaps with the second color resist unit.

7. The liquid crystal display panel according to claim 6, wherein the data line has a predetermined width and defines a strip of shaded region.

8. The liquid crystal display panel according to claim 7, wherein the first color resist unit overlaps with the second color resist unit within the strip of shaded region.

9. The liquid crystal display panel according to claim 7, wherein the borderlines of the two adjacent pixel electrode patterns are located within the strip of shaded region.

10. The liquid crystal display panel according to claim 7, wherein the common boundary is located within the strip of shaded region.

11. The liquid crystal display panel according to claim 5, wherein the liquid crystal display panel further comprises a passivation layer formed between the second substrate and the color resist layer.

12. The liquid crystal display panel according to claim 11, wherein the liquid crystal display panel further comprises a via hole penetrating through the passivation layer, the color resist layer, and the planarization layer, the pixel electrode layer coupled to the thin film transistor through the via hole.

13. The liquid crystal display panel according to claim 5, wherein the first substrate and the second substrate are curved.

14. A method for manufacturing a liquid crystal display panel,
providing a second substrate comprising a plurality of data lines, scan lines, and thin film transistors, wherein the data lines and the scan lines define a plurality of pixel units;
forming a color resist layer on the second substrate, wherein the color resist layer comprises a first color resist unit and a second color resist unit, the first color resist unit and the second color resist unit respectively disposed in two adjacent pixel units, and wherein the first color resist unit and the second color resist unit form a common boundary above the data line;
coating a planarization layer on the color resist layer;
coating a pixel electrode layer on the planarization layer; and
patterning the pixel electrode layer to form a plurality of pixel electrode patterns corresponding to the pixel units, wherein two adjacent pixel electrode patterns have borderlines located above the data line.

15. The method for manufacturing a liquid crystal display panel according to claim 14, hereinbefore coating the pixel electrode layer, further comprises:
patterning the planarization layer and the color resist layer to form a via hole penetrating through the color resist layer and the planarization layer for exposing the thin film transistor.
